(19) United States
(12) Patent Application Publication
(10) Pub. No.: US 2022/0059361 A1
(43) Pub. Date: Feb. 24, 2022

(54) ETCHING METHOD AND PLASMA PROCESSING APPARATUS

(71) Applicant: Tokyo Electron Limited, Tokyo (JP)

(72) Inventors: Michiko NAKAYA, Miyagi (JP); Taku GOHIRA, Miyagi (JP); Hyoseok SONG, Gyeonggi-do (KR); Masahiro TADOKORO, Miyagi (JP); Kentaro NUMATA, Miyagi (JP); Keita YAEGASHI, Miyagi (JP)

(21) Appl. No.: 17/445,625

(22) Filed: Aug. 23, 2021

(30) Foreign Application Priority Data
Aug. 24, 2020 (JP) 2020-141072
Jun. 22, 2021 (JP) 2021-103361

(51) Int. Cl. H01L 21/311; H01J 37/32

(52) U.S. Cl. CPC H01L 21/31116; H01J 37/32082; H01J 2237/334; H01J 37/32724

(57) ABSTRACT

An etching method for providing an etch profile is provided. The etching method includes preparing a substrate in which a laminate film is formed, the laminate film including silicon oxide films and silicon films stacked in alternation. The etching method includes cooling a surface temperature of the substrate to −40° C. or less. The etching method includes forming a plasma from gas containing hydrogen and fluorine, based on radio frequency power for plasma formation. The etching method includes etching the laminate film with the formed plasma.

### CROSS-REFERENCE TO RELATED APPLICATIONS

This patent application claims priority to Japanese Patent Applications Nos. 2020-141072, filed Aug. 24, 2020, and 2021-103361, filed Jun. 22, 2021, the contents of which are incorporated herein by reference in their entirety.

### TECHNICAL FIELD

The present disclosure relates to an etching method and a plasma processing apparatus.

### BACKGROUND

Japanese Unexamined Patent Application Publication No. 2016-39310, which is hereinafter referred to as Patent document 1, proposes a method of etching a multilayer film that includes silicon oxide films and silicon nitride films stacked in alternation. Also, WO2013/118660, which is hereinafter referred to as Patent document 2, proposes a method of etching a multilayer film that includes silicon oxide films and polycrystalline silicon films stacked in alternation.

In Patent document 2, a multilayer film is etched with a plasma formed from an etchant gas, where the etchant gas includes (i) at least one selected from the group consisting of a bromine-containing gas, a chlorine-containing gas, and an iodine-containing gas, and (ii) fluorocarbon gas.

### CITATION LIST

[Patent Document]

Patent document 1: Japanese Unexamined Patent Application Publication No. 2016-39310
Patent document 2: WO2013/118660

### SUMMARY

According to one aspect of the present disclosure, an etching method for providing an etch profile is provided. The etching method includes preparing a substrate in which a laminate film is formed, the laminate film including silicon oxide films and silicon films stacked in alternation. The etching method includes cooling a surface temperature of the substrate to −40° C. or less. The etching method includes forming a plasma from gas containing hydrogen and fluorine, based on radio frequency power for plasma formation. The etching method includes etching the laminate film with the formed plasma.

### BRIEF DESCRIPTION OF THE DRAWINGS

FIG. 1 is a cross-sectional view schematically illustrating an example of a plasma processing apparatus according to one embodiment;

FIG. 2 is a flowchart illustrating an example of an etching method according to one embodiment;

FIG. 3 is a diagram illustrating an example of the structure of an etching film according to one embodiment;

FIGS. 4A to 4C are graphs illustrating an example of the relationship between a surface temperature of a substrate and an etching characteristic according to one embodiment;

FIG. 5 is a diagram illustrating an example of the relationship, after etching, between a circularity of the bottom of a recessed portion formed in a laminate film and bending according to one embodiment;

FIGS. 6A to 6C are graphs illustrating an example of an etch rate of a given film, with respect to each ratio of a volumetric flow rate of a hydrogen-containing gas to a total sum of volumetric flow rates of the hydrogen-containing gas and a fluorine-containing gas according to one embodiment;

FIG. 7 is a diagram illustrating the principle of etching a recessed portion in a silicon oxide film by HF-based radicals, at lower temperatures;

FIG. 8 is a graph illustrating an example of the relationship between radio frequency power and a surface temperature of a substrate during etching according to one embodiment;

FIG. 9 is a graph illustrating an example of the result obtained by adding chlorine to process gas in the etching method according to one embodiment;

FIG. 10 is a graph illustrating an example of an etch rate with respect to each ratio of a volumetric flow rate of SF₆ gas to a total sum of volumetric flow rates of the SF₆ gas and NF₃ gas according to one embodiment; and

FIG. 11 is a diagram illustrating an example of bending with respect to each ratio of the volumetric flow rate of SF₆ gas to the total sum of volumetric flow rates of the SF₆ gas and NF₃ gas according to one embodiment.

### DETAILED DESCRIPTION

One or more embodiments of the present disclosure will be described with reference to the drawings. Note that in each drawing, the same numerals denote the same components, and duplicate description for the components may be omitted.

[Plasma Processing Apparatus]

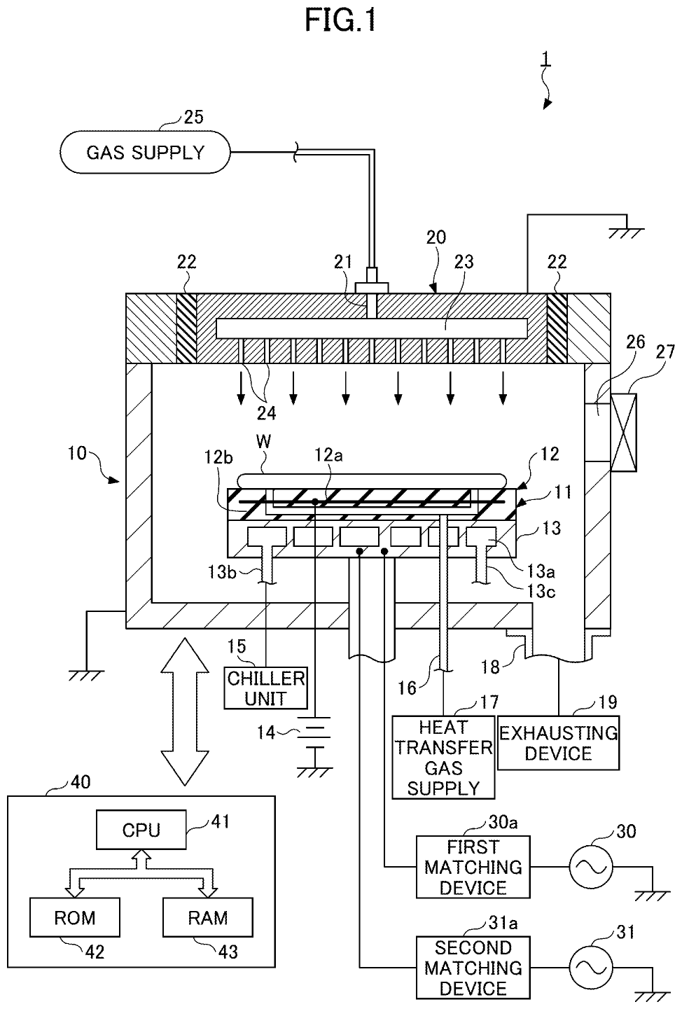

A plasma processing apparatus 1 according to one embodiment will be described with reference to FIG. 1. FIG. 1 is a cross-sectional view schematically illustrating an example of the plasma processing apparatus 1 according to one embodiment. The plasma processing apparatus 1 is a capacitively coupled plasma apparatus that includes a stage 11 and a showerhead 20 in a processing chamber 10, where the stage 11 is disposed facing the showerhead 20.

The stage 11 holds a substrate W, which is an example of a semiconductor wafer, and serves as a bottom electrode. The showerhead 20 supplies a shower of gas to the processing chamber 10. The showerhead serves as a top electrode.

For example, the processing chamber 10 is formed of an aluminum metal of which the surface is anodized. The processing chamber 10 is cylindrical and is electrically grounded. The stage 11 is provided on a bottom side of the processing chamber 10, and the substrate W is mounted on the stage W.

The stage 11 is formed of, for example, aluminum (Al), titanium (Ti), silicon carbide (SiC), or the like. The stage 11 includes an electrostatic chuck 12 and a base 13. The base 13 supports the electrostatic chuck 12. The electrostatic chuck 12 has a structure in which a chuck electrode 12a is inserted into an insulator 12b. A power source 14 is coupled to the chuck electrode 12a. The electrostatic chuck 12 attracts the substrate W through a coulomb force that is caused when the power source 14 applies a voltage to the electrostatic chuck 12.

A coolant flow path 13a is formed in an interior of the base 13. A coolant inlet line 13b and a coolant outlet line 13c are coupled to the coolant flow path 13a. A chiller unit 15 outputs a coolant (temperature-controlled medium) at a predetermined temperature, and the coolant is circulated from the coolant inlet line 13b to the coolant outlet line 13c, through the coolant flow path 13a. In such a manner, the stage 11 is cooled (temperature-controlled) and thus the substrate W is adjusted to a predetermined temperature.

A heat transfer gas supply 17 supplies heat transfer gas, such as helium gas, to a portion between the top of the electrostatic chuck 12 and the back of the substrate W, where the heat transfer gas is supplied via a gas supply line 16. Thus, efficiency in transferring heat between the electrostatic chuck 12 and the substrate W is increased, thereby resulting in improvement of the temperature control for the substrate W.

A first radio frequency power source 30 is electrically coupled to the stage 11 via a first matching device 30a. The first radio frequency power source 30 supplies radio frequency power (HF power) for plasma formation, to the stage 11. A second radio frequency power source 31 is electrically coupled to the stage 11 via a second matching device 31a. The second radio frequency power source 31 supplies radio frequency power (LF power) for biasing a voltage, to the stage 11, where the LF power is set at a frequency lower than the frequency of the HF power. For example, the first radio frequency power source 30 applies radio frequency power at 40 MHz to the stage 11. Also, for example, the second radio frequency power source 31 applies radio frequency power at 400 kHz to the stage 11. Note that the first radio frequency power source 30 may apply power at increased frequencies to the showerhead 20.

The first matching device 30a performs matching of load impedance on the stage 11-side with output (internal) impedance of the first radio frequency power source 30. The second matching device 31a performs matching of load impedance on the stage 11-side with output (internal) impedance of the second radio frequency power source 31.

The showerhead 20 closes an opening in a ceiling of the processing chamber 10, through an insulating shield ring 22, which covers the edge of the showerhead 20. A gas inlet 21 for introducing gas is formed in the showerhead 20. A diffusion compartment 23, which communicates with the gas inlet 21, is provided in an interior of the showerhead 20. Gas output from the gas supply 25 is supplied to the diffusion compartment 23 through the gas inlet 21, and then the gas is introduced from gas holes 24 to the processing chamber 10.

An exhaust port 18 is formed at the bottom of the processing chamber 10, and an exhausting device 19 is attached to the exhaust port 18. The exhausting device 19 exhausts the air in the processing chamber 10, thereby depressurizing the processing chamber 10 up to a predetermined vacuum level. A gate valve 27 that opens or closes a loading port 26 is attached to a sidewall of the processing chamber 10. In accordance with opening and closing of the gate valve 27, the substrate W is transferred into or out of the processing chamber 10 through the loading port 26.

The plasma processing apparatus 1 includes a controller 40 that controls the entire operation of the apparatus. The controller 40 includes a central processor unit (CPU) 41, a read-only memory (ROM) 42, and a random access memory (RAM) 43. The CPU 41 executes an etching process for a given substrate W, in accordance with various recipes that are stored in storage areas in the ROM 42 and the RAM 43. In a given recipe, one or more parameters to be used under a process condition are set as control information relating to the apparatus. The parameters include a processing time, pressure (gas exhaust), radio frequency power, a voltage, various flow rates of gas, a surface temperature of a given substrate (including a temperature or the like of the electrostatic chuck 12), and a temperature of a given coolant that is supplied from the chiller unit 15. Note that a given recipe including at least one of a program and a given process condition may be stored in a hard disk or a semiconductor memory. A given recipe, which is stored in a portable computer-readable storage medium such as a CD-ROM or a DVD, may be set at a predetermined location in a given storage area.

In order to perform substrate processing, opening or closing of the gate valve 27 is controlled, and then a given substrate W that is held by a transfer arm is transferred from the loading port 26 to the processing chamber 10. The transferred substrate W is mounted on the stage 11 and then is attracted by the electrostatic chuck 12. In such a manner, the given substrate W is prepared.

Next, gas is supplied from the showerhead 20 to the processing chamber 10, and then radio frequency power for plasma formation is applied to the stage 11 to thereby form a plasma. With the formed plasma, the substrate W is etched. The radio frequency power for biasing a voltage, as well as the radio frequency power for plasma formation, may be applied to the stage 11. After an etching process, an electric charge is removed from the substrate W by a removal charge process, and subsequently the substrate W is removed from the electrostatic chuck 12. Then, the substrate W is transferred out of the processing chamber 10.

The surface temperature of a given substrate (e.g., the surface temperature of a wafer) is adjusted to an appropriate temperature, by transferring, to a given substrate W, heat that results from a temperature of the electrostatic chuck 12, where the heat is transferred through the surface of the electrostatic chuck 12 and heat transfer gas, and the temperature of the electrostatic chuck 12 is adjusted to an appropriate temperature, by the chiller unit 15. Note, however, that the substrate W is exposed to a plasma formed by applying, to the stage 11, radio frequency power for plasma formation, and thus heat input from the plasma is transferred to the substrate W, or, ions drawn by applying, to the stage 11, radio frequency power for biasing a voltage are transmitted to the substrate W. For this reason, the temperature of the substrate W, e.g., a given surface temperature of the substrate W facing the formed plasma, becomes higher than an adjusted temperature of the electrostatic chuck 12. Also, in some cases, a given surface temperature of the substrate W might be increased due to thermal radiation from at least one of (i) an electrode facing the substrate W and (ii) a given sidewall of the processing chamber 10. For this reason, when the actual varying temperature of the substrate W can be measured during an etching process, or, when a temperature difference between a given adjusted temperature of the electrostatic chuck 12 and the actual varying surface temperature of the substrate W can be estimated under a process condition, a lower target temperature of the electrostatic chuck 12 may be set in order to adjust the temperature of the substrate W within a predetermined range of temperatures.

[Etching Method]

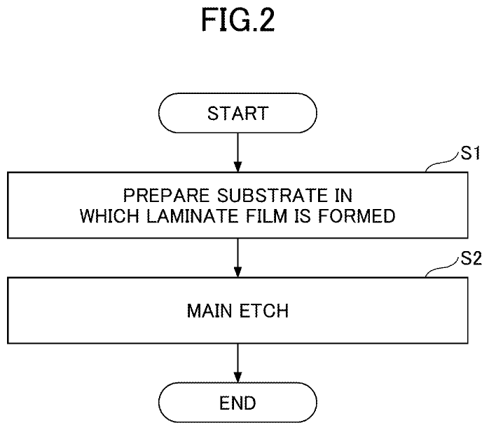

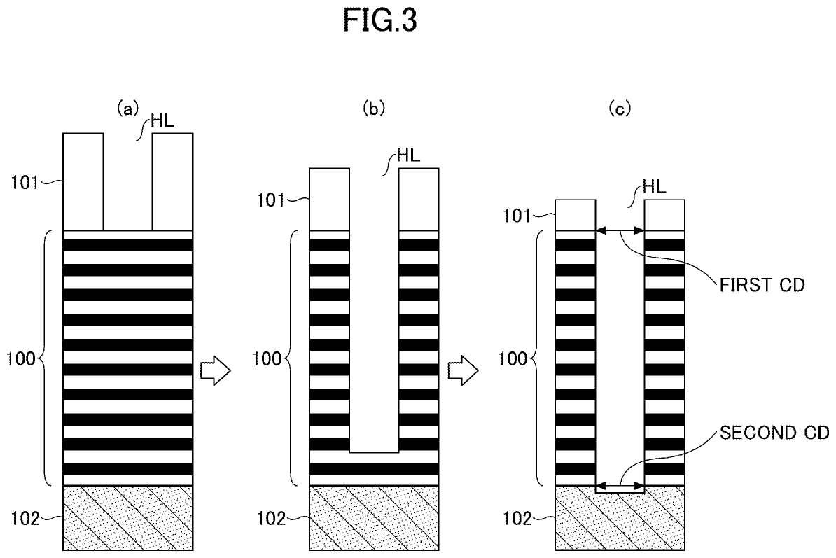

An etching method for execution by the above plasma processing apparatus 1 according to the present embodiment will be described below with reference to FIG. 2 and FIG. 3. FIG. 2 is a flowchart illustrating an example of the etching method according to the present embodiment. FIG. 3 is a diagram illustrating an example of the structure of an etching film according to the present embodiment.

In the etching method according to the present embodiment, while the surface temperature of a given substrate is cooled to −40° C. or less, a laminate film is etched. In the following description, the case where etching is performed while the surface temperature of a given substrate is adjusted to −40° C. or less is also referred to as “etching at lower temperatures”.

Referring to FIG. 2, in the etching method according to the present embodiment, a substrate N that includes a laminate film 100 and a mask 101 on the laminate film 100, as illustrated in FIG. 3(a), is prepared by mounting the substrate N on the stage (step S1). The laminate film 100 includes silicon oxide films and polycrystalline silicon films stacked in alternation. Note that instead of the polycrystalline silicon films in the laminate film 100, silicon films formed of amorphous silicon, doped silicon, or the like, may be used.

Then, under a condition in which the surface temperature of the substrate N is cooled to −40° C. or less, the laminate film is etched with a plasma formed by the plasma processing apparatus 1 (step S2). The etching in step S2 is also referred to as a main etch.

FIG. 3(a) illustrates an etching film structure in an initial state set before etching. A given substrate includes the laminate film 100, the mask 101 on the laminate film 100, and a base film 102 of the laminate film 100. The mask 101 is formed of an organic material and has an opening HL. The base film 102 is formed of, for example, polycrystalline silicon. However, the base film 102 is not limited to being formed of polycrystalline silicon, and may be formed of amorphous silicon or monocrystalline silicon. The base film 102 may be a silicide film containing a transition metal such as nickel (Ni), or may be a transition metal layer such as tungsten (W) or ruthenium (Ru).

In the main etch in step S2, a plasma from a gas containing hydrogen and fluorine is formed by applying, to the stage 11, radio frequency power for plasma formation, and the laminate film 100 is etched using the mask 101, with the formed plasma. The gas containing hydrogen and fluorine includes a combination of fluorocarbon gas (CF-based gas), hydrocarbon gas (CH-based gas), and a hydrogen-containing gas. An example of process gas includes H₂ gas and CF₄ gas. Another example of the process gas includes H₂ gas, C₄F₄ gas, CH₂F₂ gas, NF₃ gas, and SF₆ gas.

In such a manner, as illustrated in FIG. 3(b), the laminate film 100 is etched in a pattern provided by the mask 101 and a recessed portion is formed in the laminate film 100. Further, as illustrated in FIG. 3(c), the laminate film 100 is etched at lower temperatures until the base film 102 is exposed.

In the main etch described above, the laminate film 100 is etched at lower temperatures, with a plasma from process gas that is supplied to the plasma processing apparatus 1, where etching is achieved through the opening HL in the mask 101. The resulting recessed portion is formed in the laminate film 100. As illustrated in FIG. 3(c), for the recessed portion having a hole shape formed in the laminate film 100, the diameter of the recessed portion located at an interface between the mask 101 and the laminate film 100 is also referred to as a first critical dimension (CD). Also, the diameter of the recessed portion located at an interface between the base film 102 and the laminate film 100 is also referred to as a second critical dimension (CD). Note that the present embodiment will be described using the etching method in which a hole (opening HL) having an appropriate shape is formed by etching the laminate film with a plasma. However, such a method is not limiting. In the etching method according to the present embodiment, a groove having any appropriate etch profile may be formed with a plasma. For example, a given recessed portion having a striped shape may be formed.

[Temperature Dependence in Etching]

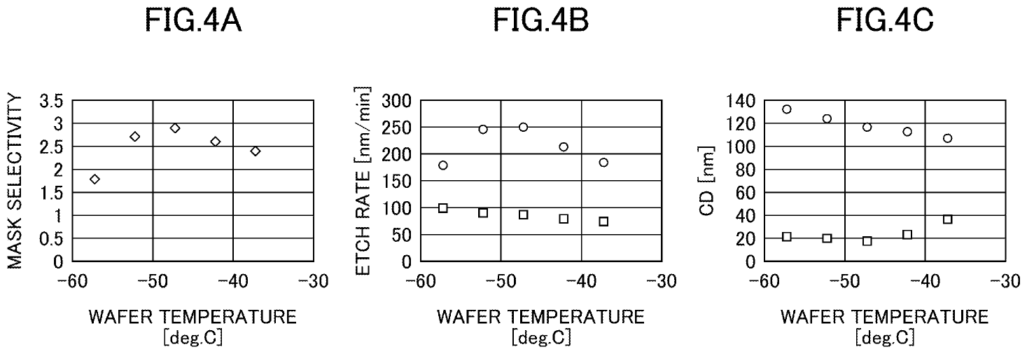

The temperature dependence of a given substrate used in the etching method according to the present embodiment will be described with reference to FIGS. 4A to 4C. FIGS. 4A to 4C are graphs illustrating an example of the relationship between the surface temperature of a given substrate W and an etching characteristic according to the present embodiment.

For example, when 3D-NAND structures or other structures are etched, laminate films 100 that include silicon oxide films and polycrystalline silicon films stacked in alternation are etched in some cases. In such cases, for temperature conditions in which laminate films including silicon oxide films and silicon nitride films stacked in alternation are etched, if either (i) a given temperature condition in which the surface temperature of a given substrate is equal to or exceeds room temperature (about 25° C.) or (ii) a given temperature condition that differs from that described in the present embodiment is applied to a given laminate film, a critical dimension (CD) resulting from bowing described below might be increased. Alternatively, in such a case, mask selectivity described below might be unsuitable for etching. For example, if a given laminate film 100 is etched by adjusting the surface temperature of a given substrate to 20° C., the critical dimension (CD) resulting from bowing is increased. Also, if a given laminate film 100 is etched by adjusting the surface temperature of a given substrate to 110° C. or 140° C., mask selectivity might be unsuitable for etching, although the critical dimension (CD) resulting from bowing is reduced.

Note that the critical dimension (CD) resulting from bowing indicates a diameter of a widest recessed portion in a given laminate film 100. The mask selectivity indicates a ratio of an etch rate of a given laminate film 100 to an etch rate of the mask 101.

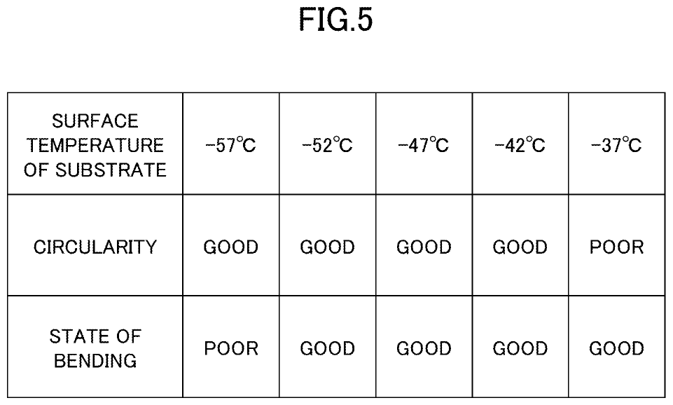

FIGS. 4A to 4C illustrate test results for etching characteristics, with respect to surface temperatures of substrates. FIG. 5 illustrates an example of the test result, after etching, of a circularity at the bottom of a given recessed portion formed in the laminate film 100 and bending according to one embodiment. In the test, as gas species, H₂ gas, C₄F₈ gas, CH₂F₂ gas, NF₃ gas, and SF₆ gas were used. In the test, process gas was supplied to the processing chamber 10 in the plasma processing apparatus 1, and then a plasma was formed from the process gas, in response to applying radio frequency power for plasma formation to the stage 11. Subsequently, the laminate film 100 was etched with the plasma.

In each of FIGS. 4A to 4C, the horizontal axis represents the surface temperature of a given substrate. The vertical axis in FIG. 4A represents the mask selectivity (indicated by “◯”). In FIG. 4B, the vertical axis represents the etch rate of the laminate film (indicated by “◯”), as well as the etch rate of a given mask (indicated by “□”). In FIG. 4C, the vertical axis represents the critical dimension (CD) resulting from bowing (indicated by “◯”), as well as the second CD at the bottom of a given recessed portion (indicated by “□”). FIG. 5 illustrates the circularity at the bottom (hole bottom) of a given recessed portion formed in the laminate film 100 after etching, as well as bending. The circularity indicates an extent to which the hole shape in cross section is circular. A better circularity in FIG. 5 indicates that the bottom of the given recessed portion was circular more exactly. In contrast, a poorer circularity in FIG. 5 indicates the bottom of the given recessed portion was like an ellipse. The bending in FIG. 5 indicates whether the given recessed portion in the laminate film 100 is tilted from the mask 101 toward the bottom of the given recessed portion, in a manner such that the given recessed portion is not etched vertically.

In the result illustrated in each of FIG. 4A and FIG. 5, when the surface temperature of a given substrate was −40° C. or higher, the mask selectivity was decreased, and the circularity at the bottom (the bottom of the hole) of a given recessed portion formed in the laminate film 100 was decreased. Specifically, when the surface temperature of the substrate was −37° C. or higher, the circularity at the bottom of the hole was decreased.

Also, when the surface temperature of the substrate was −57° C. or less, bending was increased. When the bending was increased, the resulting etch rate of the laminate film 100 might be reduced. In view of the issue described above, bending was suppressed appropriately.

Therefore, in the etching method according to the present embodiment, under a condition in which the surface temperature of a given substrate W is adjusted to −40° C. or less, the given substrate W is etched with a plasma from process gas that includes a hydrogen-containing gas and a fluorine-containing gas. In such a manner, higher mask selectivity can be obtained.

As seen from the results illustrated in FIGS. 4A and 4B, by adjusting the surface temperature of the substrate to be higher than or equal to −55° C. and less than or equal to −40° C., the mask selectivity, as well as the etch rate of the laminate film 100, could be increased. Note that when the surface temperature of the substrate was adjusted to be higher than or equal to −55° C. and less than or equal to −40° C., a sufficiently low etch rate of the mask 101 could be maintained.

As seen from the results in FIGS. 4A and 4B, when the surface temperature of the substrate was −47° C., a highest mask selectivity and a highest etch rate of the laminate film 100 were obtained. Also, it has been seen that the mask selectivity and etch rate of the laminate film 100 were increased in the range of −55° C. to −40° C.

Moreover, as seen from the result in FIG. 4C, for a difference between the critical dimension (CD) resulting from bowing and the CD (second CD) at the bottom of a given recessed portion, the difference increased as the surface temperature of the substrate decreased. The recessed portion in the laminate film 100 is etched vertically as the difference between the CD resulting from bowing and the second CD decreases. From the viewpoint described above, a smaller difference between the CD resulting from bowing and the second CD is suitable for etching.

Referring now to the result in FIG. 5, when the surface temperature of a given substrate is greater than or equal to −37° C., the circularity at the hole bottom was decreased. Further, when the surface temperature of the substrate was −57° C. or less, the sidewall of the recessed portion of the laminate film 100 was not vertically formed, thereby resulting in increased bending. When the state of bending is poor, a lower etch rate of the laminate film 100 might result. For this reason, it is preferable to suppress bending.

In other words, in order to reduce bending for a given recessed portion formed in the laminate film 100, the surface temperature of a given substrate is preferably adjusted to −55° C. or higher. In this case, the given recessed portion to be formed in the laminate film 100 is appropriately formed so as to have the substantially vertically etched shape.

Accordingly, by adjusting the surface temperature of a given substrate to −40° C. or less, the etch rate of the laminate film 100 can be increased. Further, by adjusting the surface temperature of a given substrate to be higher than or equal to −55° C. and lower than or equal to −40° C., the mask selectivity and etch rate of the laminate film 100 can be increased, and thus bending can be suppressed.

In the test in FIGS. 4A to 4C, H₂ gas, C₄F₈ gas, CH₂F₂ gas, NF₃ gas, and SF₆ gas were used, where H/(H+F), indicating a ratio of the element hydrogen (H) to a total sum of the elements hydrogen (H) and fluorine (F), was 58%.

Note that by taking into account a molecular formula of a given gas used in the test, an amount of each of the element H and the element F is determined based on (i) volumetric flow rates of given gases and (ii) the sum of values each of which is obtained by a product of valences of elements contained in a given gas among target gases.

[Gas Ratio]

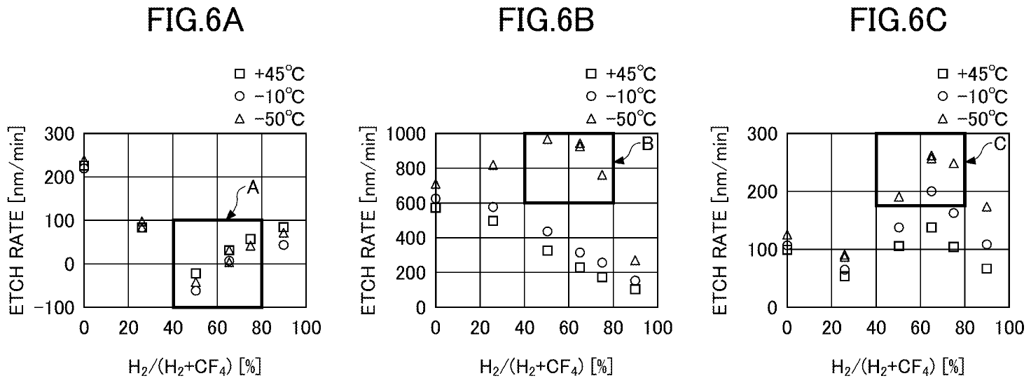

Hereafter, gas species and a given gas ratio used in the etching method according to the present embodiment will be described with reference to FIGS. 6A to 6C. FIGS. 6A to 6C are graphs illustrating an example of an etch rate with respect to each ratio of a volumetric flow rate of a hydrogen-containing gas to a total sum of volumetric flow rates of the hydrogen-containing gas and a fluorine-containing gas according to one embodiment.

In the test illustrated in FIGS. 6A to 6C, H₂ gas was used as the hydrogen-containing gas, and CF₄ gas was used as the fluorine-containing gas. Process gas of H₂ gas and CF₄ gas was supplied to the processing chamber 10 of the plasma processing apparatus 1, and then a plasma was formed from the process gas, in response to applying radio frequency power for plasma formation to the stage 11. Subsequently, the test was performed, where (i) a mask blanket of a photoresist (PR) film of an organic material, (ii) a blanket of a silicon oxide film (SiO₂), and (iii) a blanket of a polycrystalline silicon film (poly-Si) were each etched with the plasma.

In each of FIGS. 6A to 6C, the horizontal axis represents a ratio (I) of a volumetric flow rate of H₂ gas to a total volume flow rate of H₂ gas and CF₄ gas. The vertical axis in FIG. 6A represents the etch rate of a mask 101 of the photoresist (PR) film, the vertical axis in FIG. 6B represents the etch rate of a silicon oxide film (SiO₂), and the vertical axis in FIG. 6C represents the etch rate of the polycrystalline silicon film (poly-Si). The result illustrated in each of FIG. 6A to 6C includes (i) the etch rate measured under a condition in which the surface temperature of a given substrate was adjusted to 45° C. (indicated by “□”), (ii) the etch rate measured under a condition in which the surface temperature of the given substrate was adjusted to −10° C. (indicated by “◯”), and (iii) the etch rate measured under a condition in which the surface temperature of the given substrate was adjusted to −50° C. (indicated by “Δ”).

As indicated respectively by “A”, “B”, and “C” in FIGS. 6A, 6B, and 6C, under conditions in each of which the surface temperature of the substrate was adjusted to −50° C., a greater etch rate of each of the silicon oxide film and the polycrystalline silicon film was measured in comparison to the case where the surface temperature of a given substrate was adjusted to each of 45° C. and −10° C. Also, as seen from FIG. 6A, changes in a given etch rate of the mask 101 of the photoresist film were negligible with respect to conditions of the surface temperature of the substrate varying between −50° C. and 45° C.

In the test, under a condition in which a given ratio (=H₂/(H₂+CF₄)) of the volumetric flow rate of H₂ gas to the total sum of the volumetric flow rates of H₂ gas and CF₄ gas was in the range of 40% to 80%, the surface temperature of a given substrate was adjusted to −50° C. In such a condition, higher mask selectivity, as well as a higher etch rate of the laminate film 100, could be obtained.

When the result described above was applied to the condition “H/(H F)”, indicating a ratio of the element hydrogen (H) to a total sum of the elements hydrogen (H) and fluorine (F), the range of the ratio obtained was greater than or equal to 25% and less than or equal to 67%. In other words, in the etch method according to the present embodiment, by adjusting a ratio of H to a total sum of H and F that are contained in process gas, to be greater than or equal to 25% and less than or equal to 67%, higher mask selectivity for the laminate film 100, as well as a higher etch rate of the laminate film 100, can be obtained.

Note that in the tests illustrated in FIGS. 4A to 4C, the condition “H/(H+F)=58%” is satisfied, and is in the range of from 25% through 67%, as described above.

Under the above-mentioned condition of “H/(H+F)”, gas to be used in the etching method according to the present embodiment may include (i) at least one of fluorocarbon gas (CF-based gas) and hydrofluorocarbon gas (CHF-based gas), and (ii) at least one selected from among hydrofluorocarbon gas (CHF-based gas), hydrocarbon gas (CH-based gas), and a hydrogen-containing gas, where the hydrogen-containing gas is hydrogen gas (H₂) or a hydrogen halide.

Examples of the hydrofluorocarbon gas (CHF-based gas) include CH₂F₂ gas, CHF₃ gas, C₃H₂F₄ gas, and the like. Examples of the fluorocarbon gas (CF-based gas) include C₄F₄ gas, C₄F₆ gas, CF₄ gas, and the like. Examples of the hydrocarbon gas (CH-based gas) include CH₄ gas, C₂H₆ gas, C₂H₄ gas, and the like. Examples of the hydrogen halide include HF gas, HCl gas, HBr gas, HI gas, and the like.

For a plasma from process gas composed of H₂ and CF₄, hydrofluoric acid (HF) is generated by a reaction of hydrogen radicals with fluorine radicals. For example, when hydrofluoric acid is adjusted to lower temperatures of −40° C. or less, the hydrofluoric acid is more likely to condense at the bottom of a given recessed portion formed in an etching film. If the etching film is a silicon oxide film, etching of the film progresses with condensing hydrofluoric acid (HF). In view of the situation described above, a given ratio of hydrogen to fluorine is a significant parameter for the progress of etching.

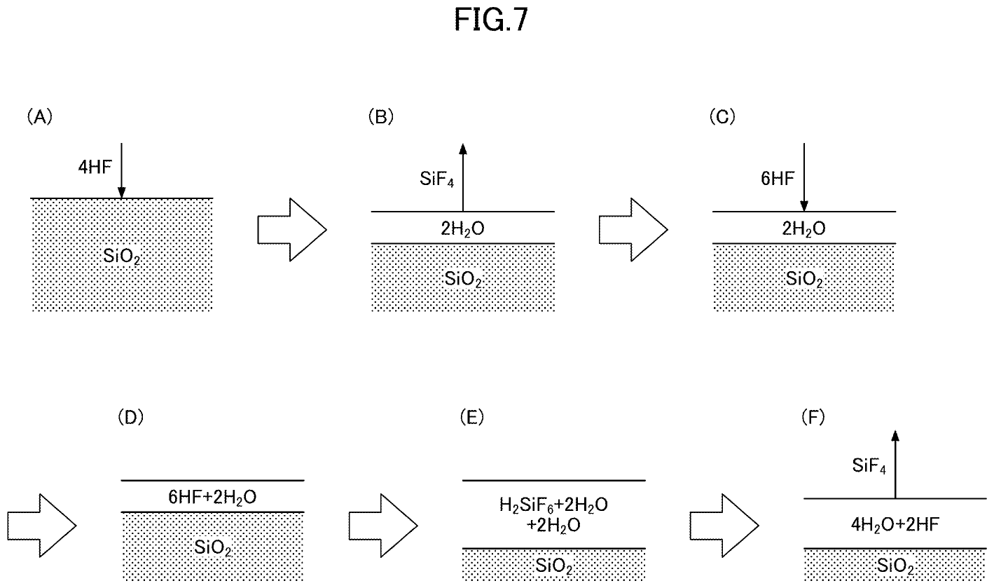

In the etching method according to the present embodiment, a ratio of H to a total sum of H and F contained in process gas is adjusted to be greater than or equal to 25% and less than or equal to 67%. In such a manner, etching can be facilitated by hydrofluoric acid (HF) condensing at the bottom of a given recessed portion. Thus, increased mask selectivity for the laminate film 100, as well as a higher etch rate of the laminate film 100, can be obtained. The significance of the adjustment of the ratio between the number of hydrogen atoms and the number of fluorine atoms to be supplied to an etching region used when a given recessed portion in a silicon oxide film is etched with the HF-based radical, at lower temperatures, will be described below with reference with FIG. 7.

[Etching with HF-Based Radicals]

FIG. 7 is a diagram illustrating the principle of etching, at lower temperatures, the recessed portion in a given silicon oxide film, with HF-based radicals.

As illustrated in FIG. 7, HF-based radicals (HF; hydrogen atoms and fluorine atoms) are supplied to the bottom of the given recessed portion formed in the silicon oxide film (SiO₂), and Si of the silicon oxide film reacts with F to thereby vaporize as SiF₄. In such a manner, the silicon oxide film is etched. In this case, water (H₂O) is formed as a reaction product ((A) and (B) of FIG. 7). In general, a vapor pressure curve shows that saturation vapor pressure of water is low. A state of water on the vapor pressure curve indicates a mixture state of liquid and gas. In view of the state described above, under a condition in which (i) pressure during etching is adjusted to be approximately between 10 mTorr and 100 mTorr, and (ii) the surface temperature of a given substrate is adjusted to be approximately between −55° C. and −40° C., it is assumed that water at the bottom of the recessed portion in the silicon oxide film is saturated, and thus water is held in a liquid state to some extent.

Then, when hydrogen fluoride is further supplied to the water, HF-based radicals react with the water, and thus hydrofluoric acid is generated ((C) and (D) of FIG. 7). In this case, it is assumed that hydrofluoric acid dissolved in water, at the bottom of the recessed portion in the silicon oxide film, facilitates etching mainly by a chemical reaction, and thus a given etch rate is significantly increased. For this reason, when the silicon oxide film is etched in the low-temperature environment, hydrogen atoms and fluorine atoms need to be supplied at an appropriate ratio.

Therefore, in the etching method according to the present embodiment, a ratio of H (hydrogen atoms) to a total sum of H (hydrogen atoms) and F (fluorine atoms) contained in process gas is adjusted to be greater than or equal to 25% and less than or equal to 67%. Thus, in etching at lower temperatures, by supplying hydrogen atoms and fluorine atoms to the laminate film 100 at an appropriate ratio, higher mask selectivity of the laminate film 100 can be obtained with increasing the etch rate of the laminate film 100.

In etching at lower temperatures, an adsorption coefficient for the HF-based radical is increased, and thus the HF-based radical is adsorbed onto the bottom of the recessed portion in a given polycrystalline silicon film. HF-based radicals themselves do not easily react with the given polycrystalline silicon film, through thermal energy. However, in a state where HF adheres to the polycrystalline silicon film, by adding energy caused by ion irradiation from a plasma, the polycrystalline silicon film reacts with the element F in the HF-based radical to thereby facilitate etching of the polycrystalline silicon film.

As described above, in the etching method according to the present embodiment, under the condition in which the surface temperature of a given substrate is cooled to 40° C. or less, a plasma is formed from process gas including a hydrogen-containing gas and a fluorine-containing gas, and then the laminate film 100 is etched with the plasma. Thus, increased mask selectivity can be obtained with increasing a given etch rate of the laminate film 100.

In this case, a ratio of hydrogen to a total sum of hydrogen and fluorine is preferably adjusted to be greater than or equal to 25% and less than or equal to 67%. Thus, etching can be facilitated mainly by chemical reactions in hydrofluoric acid.

Further, by adjusting the surface temperature of a given substrate to −40° C. or less, an increased circularity can be obtained. Also, by adjusting the surface temperature of a given substrate to −55° C. or higher, bending can be reduced.

Moreover, etching is achieved at lower temperature by using increased radio frequency power for biasing a voltage. Thus, a smaller difference between the critical dimension (CD) resulting from bowing and the second CD at a given recessed portion can be obtained with reducing the CD resulting from bowing. Accordingly, the shape of the given recessed portion formed in the laminate film 100 can be etched more appropriately, thereby resulting in the increased verticality for the given recessed portion.

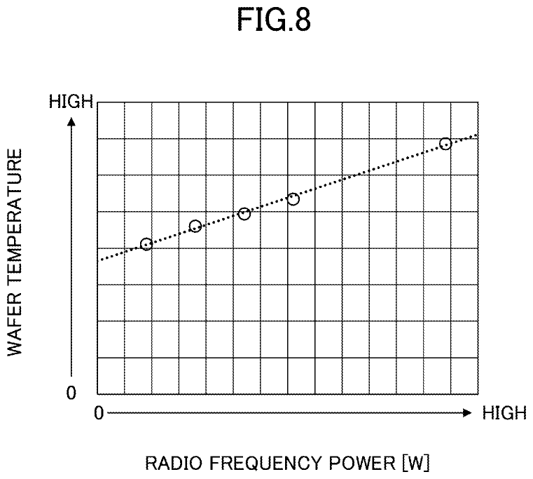

FIG. 8 is a graph illustrating an example of the relationship between radio frequency power (LF power) and the surface temperature of a given substrate, during etching according to one embodiment. In FIG. 8, the horizontal axis represents the radio frequency power (LF power), and the vertical axis represents the surface temperature of a given substrate. As illustrated in FIG. 8, during etching, as the radio frequency power increases, the surface temperature of the given substrate increases due to a heat input from a plasma. When the surface temperature of the given substrate is increased, the etch rate might be decreased. In order to avoid such an issue, the temperature of the stage 11 is controlled to decrease in accordance with increased radio frequency power. In this case, the surface temperature of the given substrate can be adjusted to be higher than or less than −55° C. and lower than or equal to −40° C. As a result, in etching at lower temperatures, mask selectivity and the etch rate of the laminate film 100 are increased, and further, the verticality of ions is increased by increasing the radio frequency power. Thus, a smaller difference between the CD resulting from bowing and the second CD at the bottom of a given recessed portion is obtained with reducing the CD resulting from bowing. Accordingly, the verticality of an etch profile can be increased.

[Addition of Chlorine]

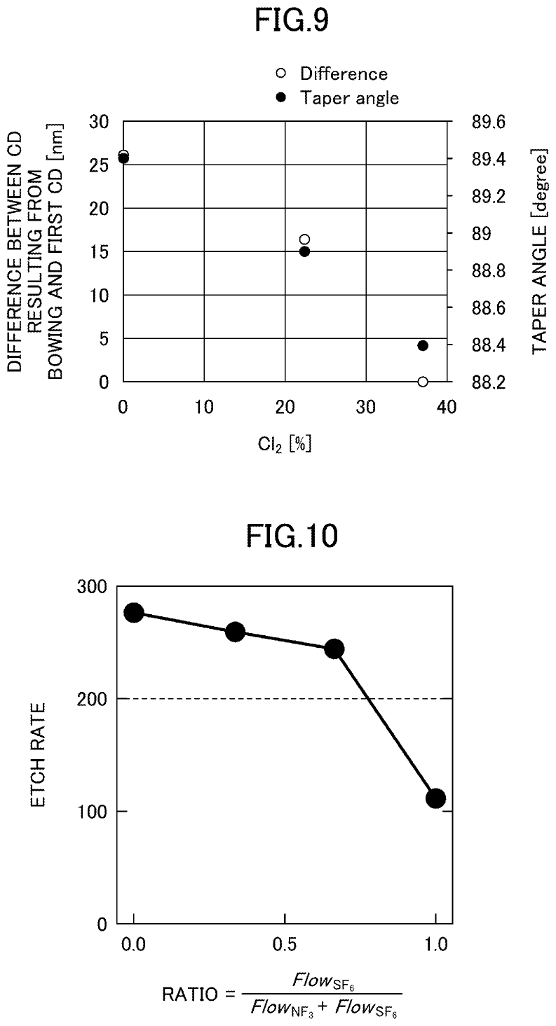

Hereafter, an improved etching shape formed when chlorine is added to process gas will be described with reference to FIG. 9. FIG. 9 is a graph illustrating an example of the result obtained by adding chlorine in the etching method according to one embodiment.

In the example in FIG. 9, in the etching process according to one embodiment, process gas is obtained by adding Cl₂ gas to H₂ gas and CF₄ gas. In FIG. 9, the horizontal axis represents a ratio of a volumetric flow rate of Cl₂ gas to a total sum of volumetric flow rates of H₂ gas and CF₄ gas. The vertical axis (left side) represents a difference between a given critical dimension (CD) resulting from bowing and a given first CD (see FIG. 3). The vertical axis (right side) represents a taper angle relative to a horizontal direction of the recessed portion formed in a given luminate film 100. The taper angle indicates the verticality of the given luminate film 100. When the recessed portion is etched vertically, the taper angle is 90°. A taper angle other than 90° indicates that the given recessed portion tapers or tapers reversely.

From the example of FIG. 9, it has been found that by adding Cl₂ gas to H₂ gas and CF₄ gas, the verticality (taper angle) enabled in etching can change with adjusting the difference between a given critical dimension resulting from bowing and a given first CD at the top of a given etched recessed portion. In other words, a given taper shape formed by etching can be changed by adjusting a given amount of Cl₂ gas that is added to H₂ gas and fluorocarbon gas. Thus, the difference between the given critical dimension (CD) resulting from bowing and a given first CD can be reduced, thereby enabling the CD resulting from bowing to be reduced, in order to provide a uniform etch profile.

The reason why the taper shape formed by etching can change will be described below. By adding Cl₂ gas to H₂ gas and fluorocarbon gas, SiCl₄ is contained in byproducts generated during etching. SiCl₄ in the byproducts is less likely to become a gaseous form, in comparison to byproducts of SiF₄ formed, during etching, by H₂ gas and fluorocarbon gas. For this reason, SiCl₄ adheres to the sidewall of a given recessed portion in the laminate film 100, and serves as a protective film against the sidewall of the given recessed portion. For the reason described above, it is considered that a smaller difference between a given critical dimension (CD) resulting from bowing and a given first CD at the top of a given etched recessed portion was obtained with reducing the given CD resulting from bowing, thereby enabling the etch profile to be provided more uniformly.

Note that in the example in FIG. 9, Cl₂ gas was added, but is not limiting. When a chlorine-containing gas, such as HCl gas or CCl₄ gas, is adopted, similar effects are obtained. Also, when gas contains bromine or iodine, such as HBr gas, HI gas, SiBr₄ or SiI₄ is formed as byproducts. As in SiCl₄, such byproducts are also less likely to become a gaseous form, in comparison to the byproducts of SiF₄. In other words, by adding a halogen-containing gas other than fluorine, a smaller difference between a given critical dimension (CD) resulting from bowing and a given first CD can be obtained with reducing the given CD resulting from bowing, thereby enabling the etch profile to be provided more uniformly.

[Ratio of SF₆ gas to NF₃ gas]

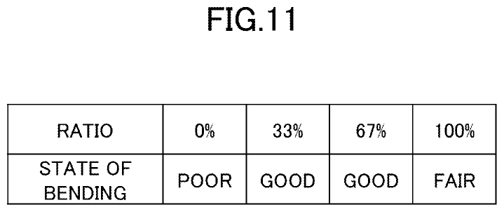

Hereafter, a ratio determined based on SF₆ gas and NF₃ gas that are contained in process gas will be described with reference to FIG. 10 and FIG. 11. FIG. 10 is a graph illustrating an example of an etch rate with respect to each ratio of a volumetric flow rate of SF₆ gas to a total volumetric flow rate of the SF₆ gas and NF₃ gas according to one embodiment. FIG. 11 is a diagram illustrating an example of bending with respect to each ratio of the volumetric flow rate of SF₆ gas to the total volumetric flow rate of the SF₆ gas and NF gas according to one embodiment.

In FIG. 10, the horizontal axis represents the ratio of the volumetric flow rate of SF₆ gas to the total sum of respective volumetric flow rates of SF₆ gas and NF₃ gas. The vertical axis represents the etch rate of the laminate film 100. In the result illustrated in FIG. 10, there is a trade-off between the etch rate and the etch profile. In other words, if a greater ratio of the volumetric flow rate of SF₆ gas to the volumetric flow rate of NF₃ gas is set, the etch rate is decreased. In contrast, if a greater ratio of the volumetric flow rate of NF₃ gas to the volumetric flow rate of SF₆ gas is set, the edge profile is not uniform. From the result relating to the etch rate illustrated in FIG. 10, the ratio of the volumetric flow rate of SF₆ gas to the total sum of volumetric flow rates of SF₆ gas and NF₃ gas is preferably 67% or less. Moreover, from the result relating to the bending illustrated in FIG. 11, the ratio of the volumetric flow rate of SF₆ gas to the total sum of volumetric flow rates of SF₆ gas and NF₃ gas is preferably greater than or equal to 33% and less than or equal to 67%. By setting the above ratio to be greater than or equal to 33% and less than or equal to 67%, an appropriate etch rate is maintained with reducing of bending. Accordingly, a more uniform edge profile can be provided.

Note that when the result described above is applied to a ratio (=H/(H+F)) of the element hydrogen (H) to a total sum of the elements hydrogen (H) and fluorine (F), the ratio is greater than or equal to 49% and less than or equal to 52%, which is in the range of from 25% through 80%, which is specified from the result in FIGS. 6A to 6C.

As described above, in the etching method and the plasma processing apparatus according to the present embodiment, the laminate film 100 that includes silicon oxide films and silicon films stacked in alternation is included in a given substrate, and is etched with a plasma from process gas containing hydrogen and fluorine. By etching at lower temperatures to adjust the surface temperature of the given substrate to −40° C. or less, higher mask selectivity is obtained, thereby allowing for an increased etch rate of the laminate film 100.

Moreover, bending can be reduced by adjusting the surface temperature of the given substrate to −55° C. or higher. Also, a given taper shape formed by etching can be changed by adding Cl₂ gas to process gas. Thus, a smaller difference between a given critical dimension resulting from bowing and a given first critical dimension at the top of a given etched recessed portion can be obtained with reducing the given critical dimension resulting from bowing. Accordingly, a more uniform etch profile can be provided.

While certain embodiments have been described, these embodiments have been presented by way of example only, and are not intended to limit the scope of the disclosures. Indeed, the embodiments described herein may be embodied in a variety of other forms. Furthermore, various omissions, substitutions and changes in the form of the embodiments described herein may be made without departing from the spirit of the disclosures. The accompanying claims and their equivalents are intended to cover such forms or modifications as would fall within the scope and spirit of the disclosures.

The plasma processing apparatus in the present disclosure is applicable to an automatic layer deposition (ALD) apparatus. Also, the plasma processing apparatus is applicable to any type selected from among a capacitively coupled plasma (CCP), an inductively coupled plasma (ICP), a radial line slot antenna (RLSA), an electron cyclotron resonance plasma (ECR), and a helicon wave plasma (HWP).

According to one aspect of the present disclosure, etch selectivity can be increased in etching a laminate film that includes silicon oxide films and silicon films stacked in alternation.

What is claimed is:

1. An etching method for providing an etch profile, the etching method comprising:
preparing a substrate in which a laminate film is formed, the laminate film including silicon oxide films and silicon films stacked in alternation;
cooling a surface temperature of the substrate to −40° C. or less;
forming a plasma from gas containing hydrogen and fluorine, based on radio frequency power for plasma formation; and
etching the laminate film with the formed plasma.

2. The etching method according to claim 1, wherein the cooling includes cooling the substrate to −55° C. or higher.

3. The etching method according to claim 1, wherein for the gas, a ratio of the element hydrogen to a total sum of the elements hydrogen and fluorine is greater than or equal to 25% and less than or equal to 67%.

4. The etching method according to claim 1, wherein the gas includes (i) at least one of fluorocarbon gas and hydrofluorocarbon gas and (ii) at least one selected from among the group consisting of hydrofluorocarbon gas, hydrocarbon gas, and a hydrogen-containing gas, the hydrogen-containing gas being hydrogen gas or a hydrogen halide gas.

5. The etching method according to claim 1, further comprising adding a halogen-containing gas to the gas, the halogen being other than fluorine.

6. The etching method according to claim 1, wherein the gas containing hydrogen and fluorine includes SF₆ gas and NF₃ gas, and
wherein a ratio of the NF₃ gas to a total sum of the SF₆ gas and the NF; gas is greater than or equal to 33% and less than or equal to 67%.

7. A plasma processing apparatus comprising:
a processing chamber; and
a controller, the controller being configured to:
cause a substrate including a laminate film to be prepared, the substrate being mounted on a stage in the processing chamber, and the laminate film including silicon oxide films and silicon films stacked in alternation;
cause a surface temperature of the substrate to be cooled to −40° C. or less;
cause a plasma from gas containing hydrogen and fluorine to be formed based on radio frequency power for plasma formation; and
cause the laminate film to be etched with the formed plasma.
